(19) United States
(12) Patent Application Publication
(10) Pub. No.: US 2015/0380070 A1
(43) Pub. Date: Dec. 31, 2015

(54) LATCH CIRCUIT AND INPUT/OUTPUT DEVICE INCLUDING THE SAME

(71) Applicant: SK hynix Inc., Incheon-si Gyeonggi-do (KR)

(72) Inventors: Duck Hwa HONG, Seoul (KR); Sang Il PARK, Suwon-si Gyeonggi-do (KR)

(21) Appl. No.: 14/517,277

(22) Filed: Oct. 17, 2014

(30) Foreign Application Priority Data
Jun. 26, 2014 (KR) 10-2014-0078886

(51) Int. Cl. G11C 8/06; G11C 8/18

(52) U.S. Cl. CPC G11C 8/06; G11C 8/18

(57) ABSTRACT

A latch circuit includes an input block configured to latch first group input addresses and second group input addresses and output first group internal addresses, according to states of select signals; and a latch block configured to latch the first group internal addresses corresponding to a first active command when a first active control signal is activated, and output the first group internal addresses and second group internal addresses as row addresses corresponding to a second active command when a second active control signal is activated.

### CROSS-REFERENCES TO RELATED APPLICATION

The present application claims priority under 35 U.S.C. §119(a) to Korean application number 10-2014-0078886, filed on Jun. 26, 2014, in the Korean Intellectual Property Office, which is incorporated herein by reference in its entirety.

### BACKGROUND

1. Technical Field

Various embodiments generally relate to a latch circuit and an input/output device including the same, and more particularly, to a semiconductor technology for controlling an address latch operation according to a change in command address pins.

2. Related Art

A semiconductor memory device generates internal command signals by combining external commands such as a chip select signal (/CS), a RAS signal (/RAS), a CAS signal (/CAS) and a write enable signal (/WE). A circuit for generating such internal command signals is referred to as a command decoder.

Meanwhile, as technology shrinks advances, a chip size is being reduced and accordingly the number of pads is being decreased. Also, as the number of channels is decreased, efforts have continuously been made to decrease the number of wire bonding pins and save costs when packaging a semiconductor device. However, in order to decrease the number of wire bonding pins, it is unavoidable to decrease the number of command address pins.

If the number of command address pins is decreased, an amount of input data capable of being inputted at a time is decreased. Accordingly, a command signal should be inputted several times to input corresponding addresses.

### SUMMARY

In an embodiment, a latch circuit may include an input block configured to latch first group input addresses and second group input addresses and output first group internal addresses, according to states of select signals. The latch circuit may also include a latch block configured to latch the first group internal addresses corresponding to a first active command when a first active control signal is activated. The latch block may also output the first group internal addresses and second group internal addresses as row addresses corresponding to a second active command when a second active control signal is activated.

In an embodiment, an input/output device may include an input block configured to latch first group input addresses and second group input addresses and output first group internal addresses, according to states of select signals. The input/output device may also include a latch block configured to latch the first group internal addresses corresponding to a first active command when a first active control signal is activated. The latch block may also output the first group internal addresses and second group internal addresses as row addresses corresponding to a second active command when a second active control signal is activated. The input/output device may also include a core region configured to be applied with the row addresses, and perform an operation corresponding to the row addresses.

### BRIEF DESCRIPTION OF THE DRAWINGS

FIG. 1 is a configuration diagram illustrating a representation of an example of an input/output device in accordance with an embodiment.

FIG. 2 is a detailed circuit diagram of an example of the input block shown in FIG. 1.

FIG. 3 is a detailed circuit diagram of an example of the latch block shown in FIG. 1.

FIG. 4 is an operation timing diagram of the input/output device in accordance with an embodiment.

FIG. 5 illustrates a block diagram of a system employing a memory controller circuit in accordance with an embodiment of the invention.

### DETAILED DESCRIPTION

Hereinafter, a latch circuit and an input/output device including the same will be described below with reference to the accompanying drawings through various embodiments. Various embodiments are directed to a technology for controlling an active operation by controlling an addressing latch operation according to a change in command address pins. According to various embodiments, advantages are provided in that it is possible to flexibly control an address latch operation in correspondence to a change in command address pins.

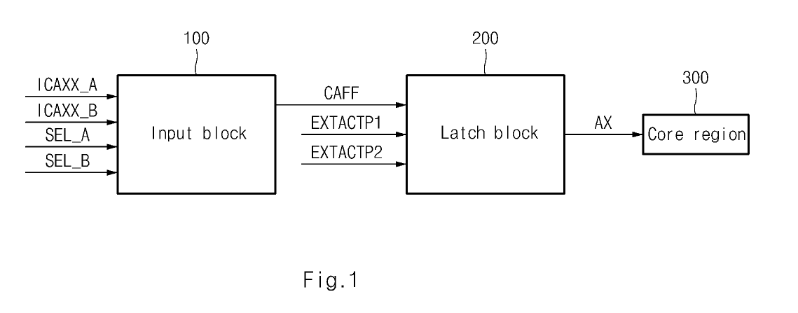

Referring to FIG. 1, a configuration diagram illustrating a representation of an example of an input/output device in accordance with an embodiment is shown.

The input/output device in accordance with an embodiment includes an input block 100, a latch block 200, and a core region 300.

The input block 100 latches first group input addresses ICAXX_A and second group input addresses ICAXX_B according to select signals SEL_A and SEL_B. The input block 100 also outputs internal addresses CAFF.

The input block 100 latches and aligns the first group input addresses ICAXX_A and the second group input addresses ICAXX_B in correspondence to the select signals SEL_A and SEL_B as command signals.

The latch block 200 latches the internal addresses CAFF according to active control signals EXTACTP1 and EXTACTP2. The latch block 200 also outputs selected row addresses AX to the core region 300.

The core region 300 performs an operation corresponding to the row addresses AX applied from the latch block 200. The core region 300 may include a plurality of banks. The operation corresponding to the row addresses AX may be a read or write active operation or a precharge operation.

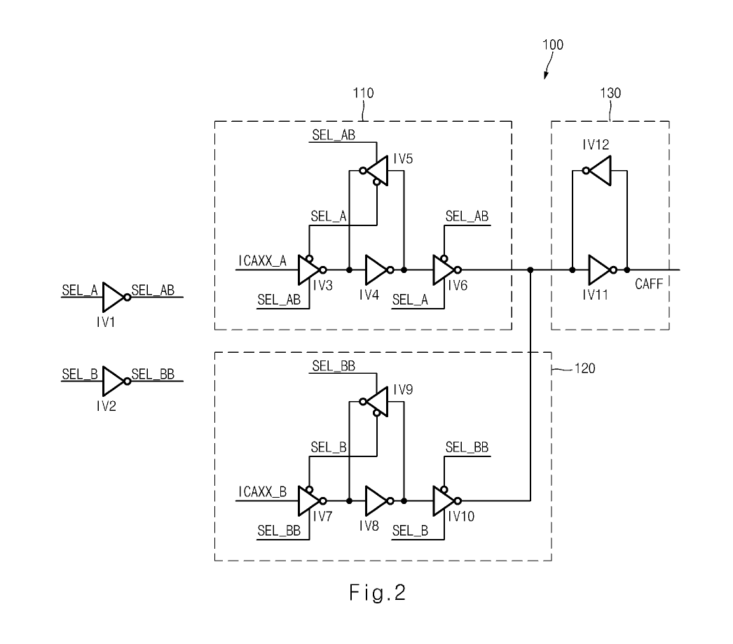

Referring to FIG. 2, a detailed circuit diagram of an example of the input block 100 shown in FIG. 1 is illustrated.

The input block 100 includes a first input unit 110, a second input unit 120, and a latch 130.

The first input unit 110 includes a plurality of inverters IV3 to IV6. The inverter IV3 inverts the first group input addresses ICAXX_A according to select signals SEL_A and SEL_AB. The inverter IV3 also drives and outputs resultant addresses. The select signal SEL_AB is a signal which results from inverting the select signal SEL_A by an inverter IV1.

The inverters IV4 and IV5 have input terminals and output terminals which are electrically coupled in a latch structure. The inverters IV4 and IV5 latch the output signals of the inverter IV3 in correspondence to the select signals SEL_AB and SEL_A. The inverter IV6 inverts the outputs of the inverter IV4 according to the select signals SEL_AB and SEL_A. The inverter IV6 also drives and outputs resultant signals.

More specifically, the first input unit 110 having such a configuration is inputted with the first group input addresses ICAXX_A in the case where the select signal SEL_A has a low level and the select signal SEL_AB has a high level. The first input unit 110 latches the inputted first group input addresses ICAXX_A where the select signal SEL_A has a high level and the select signal SEL_AB has a low level.

The second input unit 120 includes a plurality of inverters IV7 to IV10. The inverter IV7 inverts the second group input addresses ICAXX_B according to select signals SEL_B and SEL_BB. The inverter IV7 also drives and outputs resultant addresses. The select signal SEL_BB is a signal which results from inverting the select signal SEL_B by an inverter IV2.

The inverters IV8 and IV9 have input terminals and output terminals which are electrically coupled in a latch structure. The inverters IV8 and IV9 latch the output signals of the inverter IV7 in correspondence to the select signals SEL_BB and SEL_B. The inverter IV10 inverts the outputs of the inverter IV8 according to the select signals SEL_BB and SEL_B. In addition, the inverter IV10 also drives and outputs resultant signals.

More specifically, the second input unit 120 having such a configuration is inputted with the second group input addresses ICAXX_B where the select signal SEL_B has a low level and the select signal SEL_BB has a high level. The second input unit 120 latches the inputted second group input addresses ICAXX_B where the select signal SEL_B has a high level and the select signal SEL_BB has a low level.

The latch 130 latches the outputs of the first input unit 110 and the second input unit 120. The latch 130 also outputs the internal addresses CAFF. The latch 130 includes inverters IV11 and IV12 of which input terminals and output terminals are electrically coupled in a latch structure.

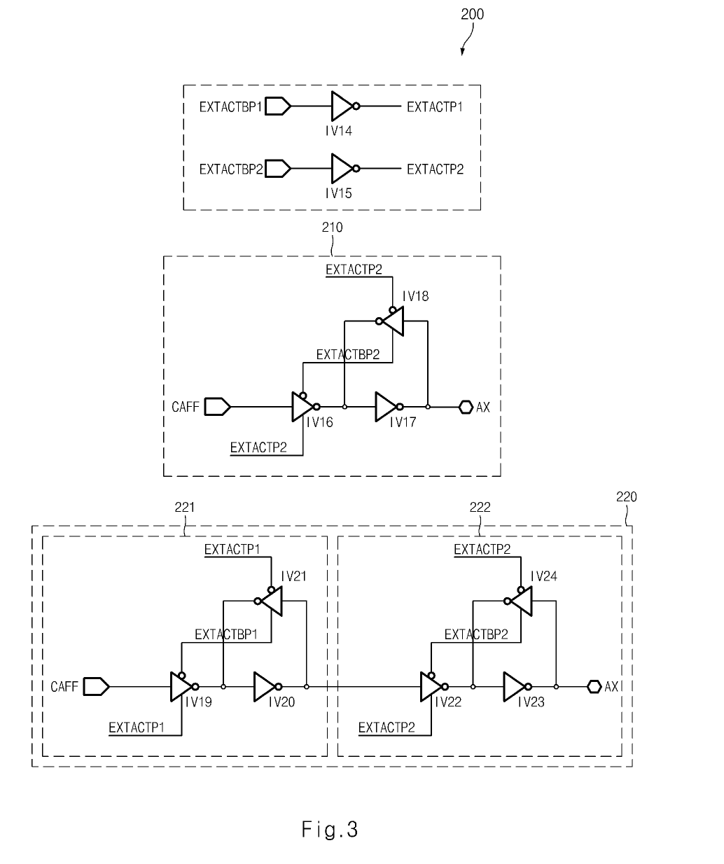

Referring to FIG. 3, a detailed circuit diagram of an example of the latch block 200 shown in FIG. 1 is illustrated.

The latch block 200 includes a first latch unit 210 and a second latch unit 220.

The first latch unit 210 latches the internal addresses CAFF according to the active control signal EXTACTP2. The first latch unit 210 also outputs the row addresses AX. The first latch unit 210 includes a plurality of inverters IV16 to IV18.

The inverter IV16 inversion-drives the internal addresses CAFF according to the states of active control signals EXTACTP2 and EXTACTBP2. The active control signal EXTACTP2 is a signal which results from inverting the active control signal EXTACTBP2 by an inverter IV15.

The inverters IV17 and IV18 which are electrically coupled in a latch structure latch the outputs of the inverter IV16 according to the active control signals EXTACTP2 and EXTACTBP2 and selectively output the row addresses AX.

More specifically, the first latch unit 210 having such a configuration is inputted with the internal addresses CAFF (for example, CAFF<0:9>) where the active control signal EXTACTP2 has a low level and the active control signal EXTACTBP2 has a high level.

The first latch unit 210 latches the inputted internal addresses CAFF (for example, CAFF<0:9>) and outputs the row addresses AX (for example, AX<0:9>) where the active control signal EXTACTP2 has a high level and the active control signal EXTACTBP2 has a low level.

The second latch unit 220 includes a first row address latch section 221 and a second row address latch section 222. The first row address latch section 221 latches the internal addresses CAFF according to active control signals EXTACTP1 and EXTACTBP1. The active control signal EXTACTP1 is a signal which results from inverting the active control signal EXTACTBP1 by an inverter IV14.

The second row address latch section 222 latches the outputs of the first row address latch section 221 according to the active control signals EXTACTP2 and EXTACTBP2. In addition, the second row address latch section 222 also outputs the row addresses AX.

The first row address latch section 221 includes a plurality of inverters IV19 to IV21. The inverter IV19 inversion-drives the internal addresses CAFF according to the states of the active control signals EXTACTBP1 and EXTACTP1. The inverters IV20 and IV21 selectively latch the outputs of the inverter IV19 according to the active control signals EXTACTP1 and EXTACTBP1.

More specifically, the first row address latch section 221 having such a configuration is inputted with the internal addresses CAFF (for example, CAFF<10:14>) where the active control signal EXTACTP1 has a low level and the active control signal EXTACTBP1 has a high level. The first row address latch section 221 latches and outputs the inputted internal addresses CAFF (for example, CAFF<10:14>) where the active control signal EXTACTP1 has a high level and the active control signal EXTACTBP1 has a low level.

The second row address latch section 222 includes a plurality of inverters IV22 to IV24. The inverter IV22 inversion-drives the outputs of the inverter IV20 according to the states of the active control signals EXTACTBP2 and EXTACTP2. The inverters IV23 and IV24 latch the outputs of the inverter IV22 according to the active control signals EXTACTP2 and EXTACTBP2, and selectively output the row addresses AX.

More specifically, the second row address latch section 222 having such a configuration is inputted with the outputs of the first row address latch section 221 where the active control signal EXTACTP2 has the low level and the active control signal EXTACTBP2 has the high level. The second row address latch section 222 latches the inputted internal addresses CAFF (for example, CAFF<10:14>) and outputs the row addresses AX (for example, AX<10:14>) where the active control signal EXTACTP2 has the high level and the active control signal EXTACTBP2 has the low level.

The latch block 200 having such a configuration stores in advance the internal addresses CAFF in the first row address latch section 221 of the second latch unit 220 where the active control signal EXTACTP1 is activated. Further, the latch block 200 simultaneously outputs the row addresses AX stored in the second latch unit 220 and the row addresses AX stored in the first latch unit 210 at a time the active control signal EXTACTP2 is activated.

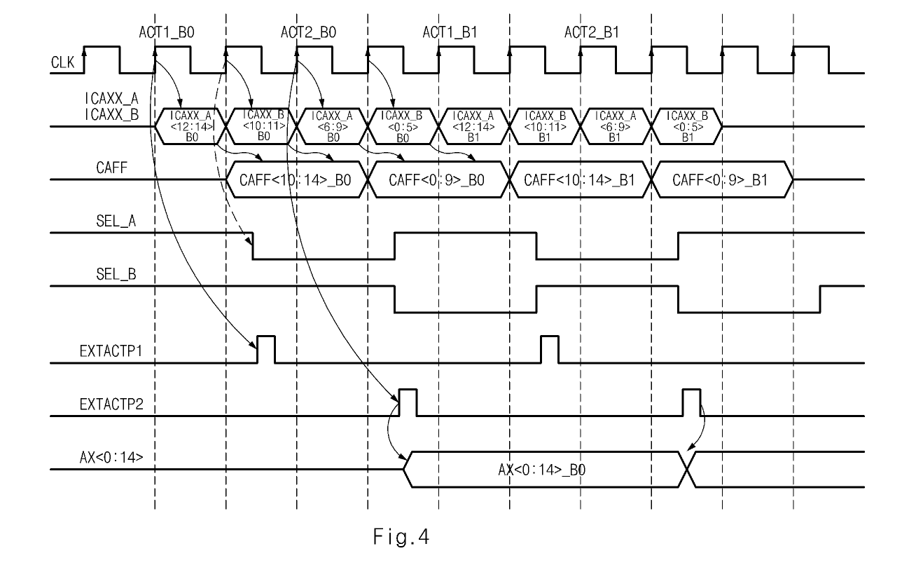

The operation processes of the input/output device in accordance with an embodiment, configured as mentioned above, will be described below with reference to the operation timing diagram of FIG. 4.

In an embodiment, in order to input an active command, information on the numbers of bank addresses and row addresses should be inputted. Accordingly, it is difficult to receive necessary information through one command signal. In addition, an active command should be inputted at least two times.

If a first active command ACT1 corresponding to a bank 0 is enabled to a high level, first group input addresses ICAXX_A<12:14> are inputted. The first group input addresses ICAXX_A<12:14> are inputted in synchronization with the rising edge of a first clock CLK. The first group input addresses ICAXX_A<12:14> are inputted for one cycle of the clock CLK.

If a second clock CLK corresponding to the first active command ACT1 is enabled, second group input addresses ICAXX_B<10:11> are inputted. The second group input addresses ICAXX_B<10:11> are inputted in synchronization with the rising edge of the second clock CLK. The second group input addresses ICAXX_B<10:11> are inputted for one cycle of the clock CLK.

Thereafter, in the input block 100, the first group input addresses ICAXX_A<12:14> are first inputted to and latched by the first input unit 110 according to the select signal SEL_A. When the select signal SEL_A transitions to the low level at the rising edge of the clock CLK, the first group input addresses ICAXX_A<12:14> are latched. The select signal SEL_A is a signal which transitions to the low level when a predetermined time passes after the first active command ACT1 is enabled.

The input block 100 latches the second group input addresses ICAXX_B<10:11> until the select signal SEL_A transitions to the high level. In other words, the input block 100 latches the first group input addresses ICAXX_A<12:14> and also the second group input addresses ICAXX_B<10:11> corresponding to the bank 0 and outputs first group internal addresses CAFF<10:14> during a period in which the select signal SEL_A has the low level.

For instance, in an input/output device of an LPDDR4 specification, active commands ACT1 and ACT2 are inputted by the unit of 4 clocks for one bank 0. In an embodiment, the first group input addresses ICAXX_A<12:14> are inputted by the unit of 1 clock, and the second group input addresses ICAXX_B<10:11> are inputted by the unit of 1 clock. As a result, the first group input addresses ICAXX_A<12:14> and the second group input addresses ICAXX_B<10:11> are latched by the unit of total 2 clocks.

Namely, addresses are inputted two times by the unit of 2 clocks for each of the active commands ACT1 and ACT2. The first group input addresses ICAXX_A<12:14> inputted in response to the first clock CLK of the first active command ACT1, are latched, and then outputted simultaneously with the second group input addresses ICAXX_B<10:11>.

Next, if a second active command ACT2 corresponding to the bank 0 is enabled to a high level, third group input addresses ICAXX_A<6:9> are inputted. The third group input addresses ICAXX_A<6:9> are inputted in synchronization with the rising edge of a first clock CLK. The third group input addresses ICAXX_A<6:9> are inputted for one cycle of the clock CLK.

If a second clock CLK corresponding to the second active command ACT2 is enabled, fourth group input addresses ICAXX_B<0:5> are inputted. The fourth group input addresses ICAXX_B<0:5> are inputted in synchronization with the rising edge of the second clock CLK. The fourth group input addresses ICAXX_B<0:5> are inputted for one cycle of the clock CLK.

Thereafter, in the input block 100, the third group input addresses ICAXX_A<6:9> are first inputted to and latched by the first input unit 110 according to the select signal SEL_B. When the select signal SEL_B transitions to the low level at the rising edge of the clock CLK, the third group input addresses ICAXX_A<6:9> are latched. When the select signal SEL_B transitions to the low level, the select signal SEL_A transitions to the high level. The select signal SEL_B is a signal which transitions to the low level when a predetermined time passes after the second active command ACT2 is enabled.

The input block 100 latches the fourth group input addresses ICAXX_B<0:5> until the select signal SEL_B transitions to the high level. In other words, the input block 100 latches the third group input addresses ICAXX_A<6:9> and the fourth group input addresses ICAXX_B<0:5> corresponding to the bank 0 and outputs second group internal addresses CAFF<0:9> during a period in which the select signal SEL_B has the low level.

The active control signals EXTACTP1 and EXTACTP2 are signals which transition to activated states of the high levels when a predetermined delay time passes after the active commands ACT1, ACT2, . . . are inputted from an exterior. More specifically, the active control signal EXTACTP1 is enabled as a high level pulse in synchronization with the rising edge of the active command ACT1. The active control signal EXTACTP2 is enabled as a high level pulse in synchronization with the rising edge of the active command ACT2.

It was described as an example in an embodiment that the active control signals EXTACTP1 and EXTACTP2 are activated in synchronization with the rising edges of the active commands ACT1 and ACT2. However, the embodiment is not limited to such, and it is to be noted that the active control signals EXTACTP1 and EXTACTP2 may be activated in synchronization with the falling edges of the active commands ACT1 and ACT2.

The active control signals EXTACTP1 and EXTACTP2 are activated to the high levels with a predetermined time interval. In other words, the active control signal EXTACTP1 is activated to the high level earlier than the active control signal EXTACTP2. The active control signal EXTACTP1 is activated to the high level at a time when the select signal SEL_A transitions to the low level. The active control signal EXTACTP2 is activated to the high level at a time when the select signal SEL_B transitions to the low level.

According to these facts, the active control signal EXTACTP1 first transitions to the high level according to the first active command ACT1 corresponding to the bank 0. The active control signal EXTACTP1 is a signal which operates in synchronization with the clock CLK and is activated to the high level when a predetermined time passes after the external active command ACT1 is activated.

Even when addresses corresponding to different banks are successively inputted, since address latches are disposed in the respective banks, the addresses may be stored in the same way according to the active control signal EXTACTP1.

Afterwards, the select signal SEL_B transitions to the low level. At this time, the active control signal EXTACTP2 is activated to the high level at the second clock CLK of the second active command ACT2.

As the active control signal EXTACTP1 transitions to the high level, the first row address latch section 221 latches the internal addresses CAFF<10:14>. At the time when the active control signal EXTACTP2 is activated, the internal addresses CAFF<10:14> latched by the first row address latch section 221 and the internal addresses CAFF<0:9> stored in the first latch unit 210 are combined. Accordingly, when the active control signal EXTACTP2 is activated, row addresses AX<0:14> corresponding to the bank 0 are simultaneously outputted to the core region 300.

Namely, if the active control signal EXTACTP2 is activated, the row addresses AX<0:14> are outputted to the core region 300 during a period before the next active control signal EXTACTP2 is enabled. The core region 300 performs an active operation such as a read or write operation or a precharge operation for a corresponding bank by using the row addresses AX<0:14>.

It was described as an example in an embodiment that the number of the row addresses AX is 15. However, the embodiment is not limited to such. In addition, it is to be noted that the number of row addresses may be changed according to the number of banks or other component elements.

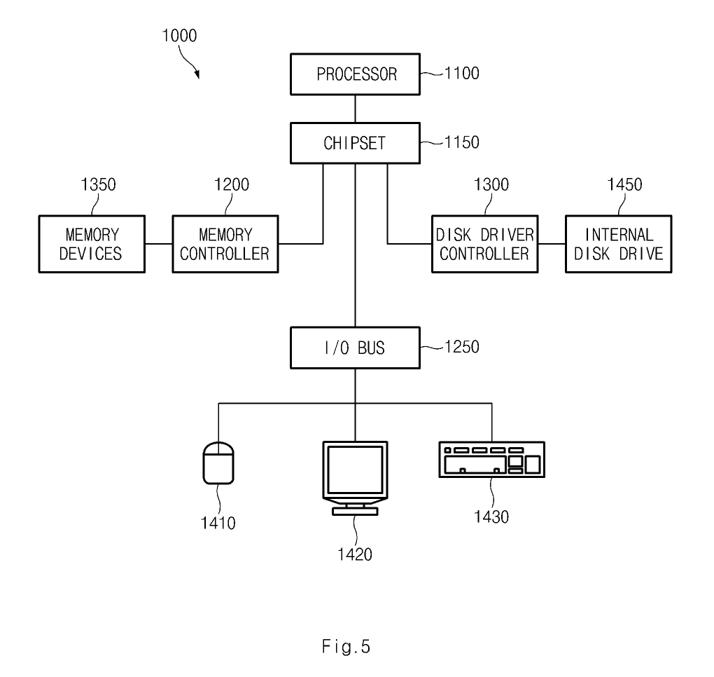

Referring to FIG. 5, a system 1000 may include one or more processors 1100. The processor 1100 may be used individually or in combination with other processors. A chipset 1150 may be operably electrically coupled to the processor 1100. The chipset 1150 is a communication pathway for signals between the processor 1100 and other components of the system 1000. Other components of the system 1000 may include a memory controller 1200, an input/output (“I/O”) bus 1250, and a disk drive controller 1300. Depending on the configuration of the system 1000, any one of a number of different signals may be transmitted through the chipset 1150.

The memory controller 1200 may be operably electrically coupled to the chipset 1150. The memory controller 1200 can receive a request provided from the processor 1100 through the chipset 1150. The memory controller 1200 may be operably electrically coupled to one or more memory devices 1350. The memory device 1350 may include the input/output device described above.

The chipset 1150 may also be electrically coupled to the I/O bus 1250. The I/O bus 1250 may serve as a communication pathway for signals from the chipset 1150 to I/O devices 1410, 1420 and 1430. The I/O devices 1410, 1420 and 1430 may include a mouse 1410, a video display 1420, or a keyboard 1430. The I/O bus 1250 may employ any one of a number of communications protocols to communicate with the I/O devices 1410, 1420, and 1430.

The disk drive controller 1300 may also be operably electrically coupled to the chipset 1150. The disk drive controller 1300 may serve as the communication pathway between the chipset 1150 and one or more internal disk drives 1450. The disk drive controller 1300 and the internal disk drives 1450 may communicate with each other or with the chipset 1150 using virtually any type of communication protocol.

As is apparent from the above descriptions, according to an embodiment, since a process to generate bank active signals and a process to latch addresses are differentiated according to a change in command address pins, it is possible to flexibly cope with the pin change without changing a specification.

In a system configured by a plurality of semiconductor devices, a memory device is used as a space to store data. If a memory controller such as a central processing unit (CPU) or a graphic processing unit (GPU) applies commands and addresses for input/output of data, to the memory device, the memory device performs an operation of storing the data inputted from the controller, in a memory cell region corresponding to the inputted addresses, or outputting the data stored in the memory cell region corresponding to the inputted addresses.

While various embodiments have been described above, it will be understood to those skilled in the art that the embodiments described are by way of example only. Accordingly, the latch circuit and the input/output device including the same described should not be limited based on the described embodiments.

What is claimed is:

1. A latch circuit comprising:
an input block configured to latch first group input addresses and second group input addresses and output first group internal addresses according to states of select signals; and
a latch block configured to latch the first group internal addresses corresponding to a first active command when a first active control signal is activated, and output the first group internal addresses and second group internal addresses as row addresses corresponding to a second active command when a second active control signal is activated.

2. The latch circuit according to claim 1, wherein the input block is inputted with addresses by the unit of 2 clocks in correspondence to the first active command and the second active command.

3. The latch circuit according to claim 2, wherein the input block is inputted with the first group input addresses and the second group input addresses in synchronization with the 2 clocks.

4. The latch circuit according to claim 1, wherein the input block comprises:
a first input unit configured to latch the first group input addresses according to a state of a first select signal;
a second input unit configured to latch the second group input addresses according to a state of a second select signal; and
a latch configured to latch an output of the first input unit and an output of the second input unit, and output the second group internal addresses.

5. The latch circuit according to claim 4, wherein the first input unit is inputted with the first group input addresses when the first select signal has a low level, and latches the first group input addresses for a predetermined time when the first select signal has a high level.

6. The latch circuit according to claim 4, wherein the second input unit is inputted with the second group input addresses when the second select signal has a low level, and latches the second group input addresses for a predetermined time when the second select signal has a high level.

7. The latch circuit according to claim 1, wherein the latch block comprises:
a first latch unit configured to latch the second group internal addresses and output the row addresses when the second active control signal is activated; and
a second latch unit configured to latch the first group internal addresses when the first active control signal is activated, and output the latched addresses as the row addresses when the second active control signal is activated.

8. The latch circuit according to claim 7, wherein the second latch unit comprises:
a first row address latch section configured to latch the first group internal addresses when the first active control signal is activated; and
a second row address latch section configured to output outputs of the first row address latch section as the row addresses when the second active control signal is activated.

9. The latch circuit according to claim 1, wherein the first active control signal is activated at a different time from the second active control signal.

10. The latch circuit according to claim 9, wherein the first active control signal is activated to a high level before than the second active control signal.

11. An input/output device comprising:
an input block configured to latch first group input addresses and second group input addresses and output first group internal addresses according to states of select signals;
a latch block configured to latch the first group internal addresses corresponding to a first active command when a first active control signal is activated, and output the first group internal addresses and second group internal addresses as row addresses corresponding to a second active command when a second active control signal is activated; and
a core region configured to be applied with the row addresses, and perform an operation corresponding to the row addresses.

12. The input/output device according to claim 11, wherein the input block is inputted with addresses by the unit of 2 clocks in correspondence to the first active command and the second active command.

13. The input/output device according to claim 12, wherein the input block is inputted with the first group input addresses and the second group input addresses in synchronization with the 2 clocks.

14. The input/output device according to claim 11, wherein the input block comprises:
a first input unit configured to latch the first group input addresses according to a state of a first select signal;
a second input unit configured to latch the second group input addresses according to a state of a second select signal; and
a latch configured to latch an output of the first input unit and an output of the second input unit, and output the second group internal addresses.

15. The input/output device according to claim 14, wherein the first input unit is inputted with the first group input addresses when the first select signal has a low level, and latches the first group input addresses for a predetermined time when the first select signal has a high level.

16. The input/output device according to claim 14, wherein the second input unit is inputted with the second group input addresses when the second select signal has a low level, and latches the second group input addresses for a predetermined time when the second select signal has a high level.

17. The input/output device according to claim 11, wherein the latch block comprises:
a first latch unit configured to latch the second group internal addresses and output the row addresses when the second active control signal is activated; and
a second latch unit configured to latch the first group internal addresses when the first active control signal is activated, and output the latched addresses as the row addresses when the second active control signal is activated.

18. The input/output device according to claim 17, wherein the second latch unit comprises:
a first row address latch section configured to latch the first group internal addresses when the first active control signal is activated; and
a second row address latch section configured to output outputs of the first row address latch section as the row addresses when the second active control signal is activated.

19. The input/output device according to claim 11, wherein the first active control signal is activated at a different time than the second active control signal.

20. The input/output device according to claim 11, wherein the core region performs an active operation or a precharge operation in correspondence to the row addresses.
